(19) United States
(12) Patent Application Publication
(10) Pub. No.: US 2011/0006648 A1
(43) Pub. Date: Jan. 13, 2011

(54) HOUSING

(75) Inventor: Friedhelm Rose, Porta Westfalica (DE)

Correspondence Address: ROBERT W. BECKER & ASSOCIATES, 707 HIGHWAY 333, SUITE B, TIJERAS, NM, 87059-7507, US

(73) Assignee: ROLEC Gehäuse-Systeme GmbH, Bad Oeynhausen (DE)

(21) Appl. No.: 12/745,958

(22) PCT Filed: Oct. 30, 2008
(86) PCT No.: PCT/DE08/01757

§ 371 Date: Sep. 1, 2010

(30) Foreign Application Priority Data
Dec. 3, 2007 (DE) 10 2007 058 079.9

(51) Int. Cl. H05K 5/02

(52) U.S. Cl. 312/223.1

(57) ABSTRACT

A housing, especially for accommodating electrical and electronic components, comprising a lower portion, a cover adapted to be secured to the lower portion, and a holding element adapted to be mounted on a planar surface. The lower portion, along with the cover secured thereto, is adapted to be releasably arrested on the holding element, under spring tension.

The present invention relates to a housing, especially for accommodating electrical and electronic components, including a lower portion that is to be secured to a planar surface, and a hood-shaped cover that can be secured thereto, in particular via a screw connection.

Such housings are used, for example, in the machine-building industry and in the vehicle industry, and are secured on suitable planar walls or floor surfaces of the machines or vehicles. For this purpose, disposed in the corner regions of the lower portion of the housing, beyond the inner space, are channels for fastening screws that for aesthetic reasons are covered by the housing cover, whereby either separate channels for the securement of the lower portion of the housing to the planar surface and for the securement of the cover to the lower portion are provided, or channels having a relatively complicated configuration of the securement means are provided for both connections (e.g. DE-PS 36 18 973). In both cases, the channels increase the dimensions of the housing. Furthermore, when a disassembly of the housing is required, for example for servicing or replacement of electrical and electronic components housed therein, the cover must first be removed before the lower portion can be unscrewed from the securement surface.

It is therefore an object of the present invention to provide a housing having straightforward and space-saving assembly means, that is easy to service, and that has an aesthetic appearance.

Proceeding from a housing of the aforementioned general type, the stated object is inventively realized in that a holding element serves for the securement of the lower portion upon the planar surface, wherein the holding element is first to be mounted on the planar surface, and the lower portion, which is provided with the cover, is then to be releasably arrested on the holding element, under spring tension.

As a consequence of the inventive configuration, the securement channels are eliminated, thus saving considerable material (generally aluminum, thermoplastic material or glass-reinforced polyester), and the housing is produced more economically, and with more uniform walls, and also more simply. The securement of the housing on the planar surface through the base of the lower portion with the cover removed is eliminated, and the housing, with the components accommodated therein, can rapidly be replaced or disassembled for service purposes, and can subsequently again be rapidly mounted. The shape of the housing can be freely and attractively designed, without having to be limited by the securement means. The securement of the cover to the lower portion of the housing can be effected by screws that extend from below through the lower portion, so that the heads of the screws are not visible when the housing is arrested.

Pursuant to one embodiment of the invention, the holding element and the lower portion of the housing are provided with overlapping or interengaging surfaces, between which arresting or latching means are disposed.

The holding element is preferably comprised of a square or rectangular base plate that can be screwed onto the planar surface and that has two legs that extend at right angles therefrom on opposite sides, whereby a frame is formed on the underside of the lower portion of the housing that is dimensioned such that it positively extends about or embraces the base plate and the legs of the holding element. This ensures that the housing is held at its securement position in a non-displaceable and reproducible manner.

The legs and the frame advantageously have approximately the same height. In such a case, the securement of the housing on the planar surface is entirely invisible.

It is advantageous if on the side adjacent to one of the legs, the frame is provided with at least one opening for the introduction of a tongue or tab of the leg that fits into this opening, while on the opposite side, between the frame and the leg adjacent thereto, a latching or arresting mechanism is provided. If the arresting mechanism is then comprised of a spring-biased ball, or is embodied in the manner of a door lock, which falls or snaps into an arresting receiving means via a glide surface provided on the frame, a latching or arresting without having to use a special tool is possible.

Pursuant to a further embodiment of the invention, elastically resilient means are provided on the holding element that in the arrested state bias the holding element and the lower portion of the housing against one another. This prevents a “chattering” or “rattling” of the securement.

The invention will be explained in greater detail subsequently with the aid of exemplary embodiments shown in the accompanying drawings, in which:

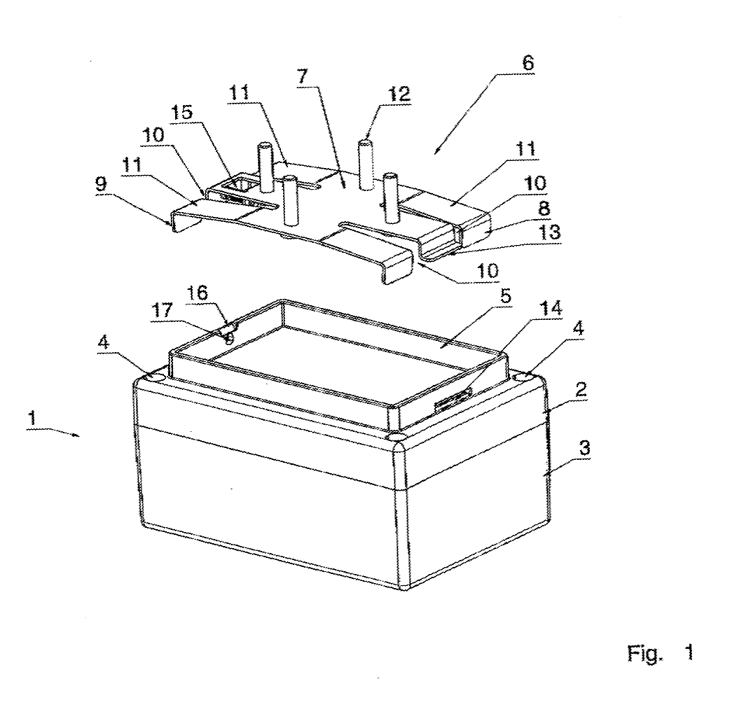

FIG. 1 is a perspective view of one exemplary embodiment of a holding element and a housing that can be arrested thereon;

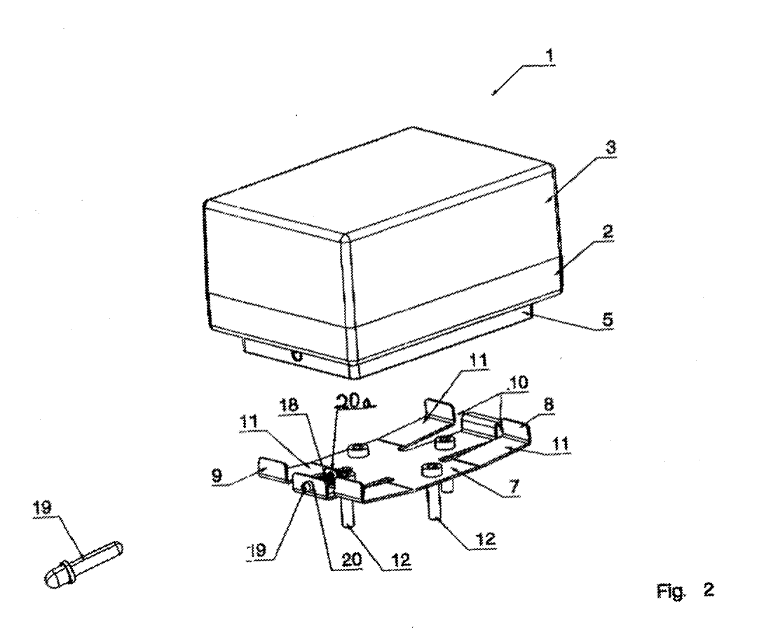

FIG. 2 is a perspective view of the arrangement of FIG. 1 with the arresting mechanism from a different view-point or direction of viewing;

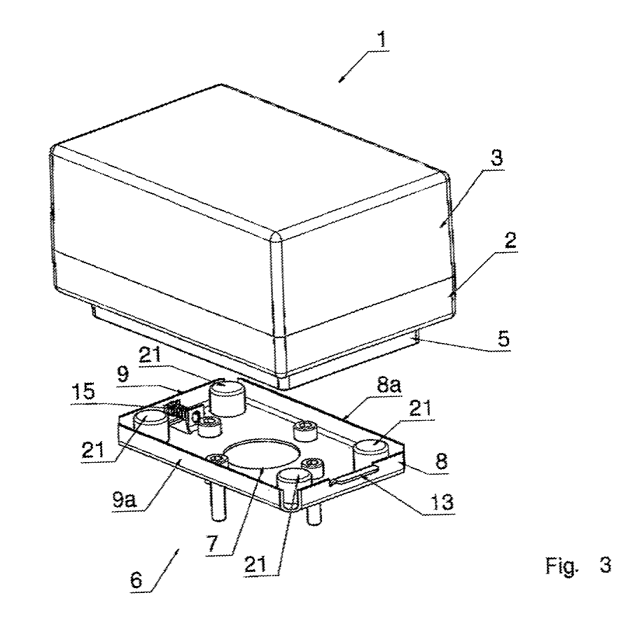

FIG. 3 shows a second exemplary embodiment of a holding element and the housing that can be arrested thereon;

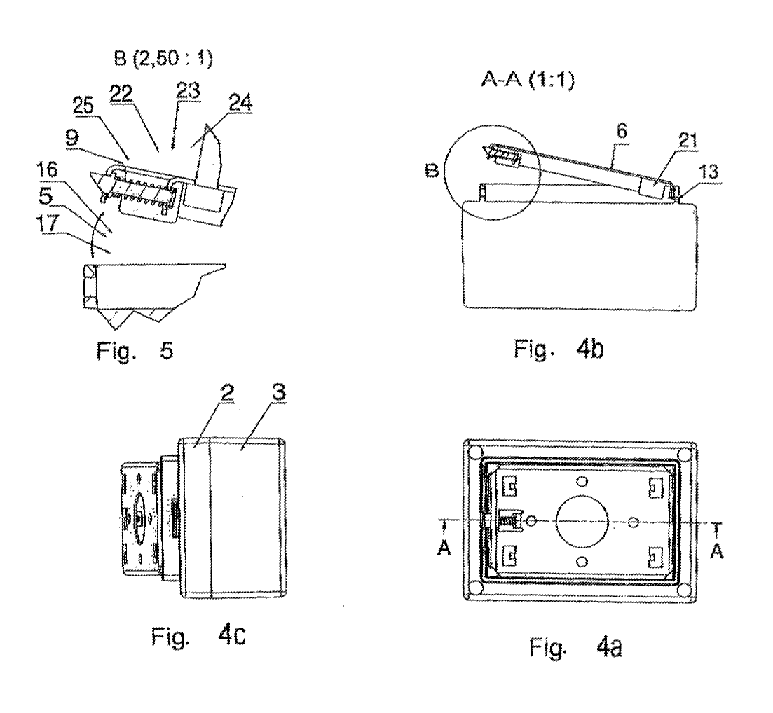

FIG. 4a is a bottom view of the embodiment of FIG. 3 with a modified arresting mechanism in a 1:1 scale;

FIG. 4b is a section taken along the line A-A in FIG. 4a prior to the arresting or latching of the housing in the holding element;

FIG. 4c is a side view from FIG. 4;

FIG. 5 shows the arresting mechanism in the encircled area B of FIG. 4b in an enlarged scale;

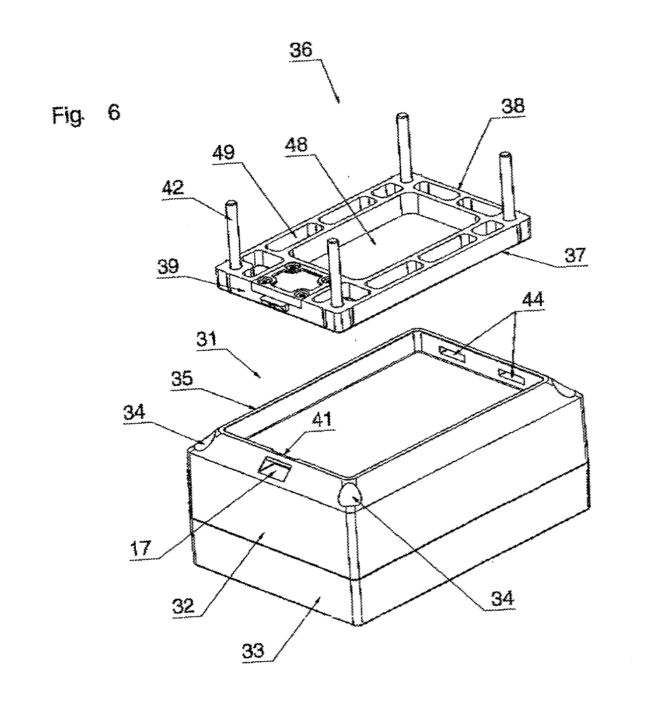

FIG. 6 shows a third exemplary embodiment of a holding element and a housing that can be arrested thereon;

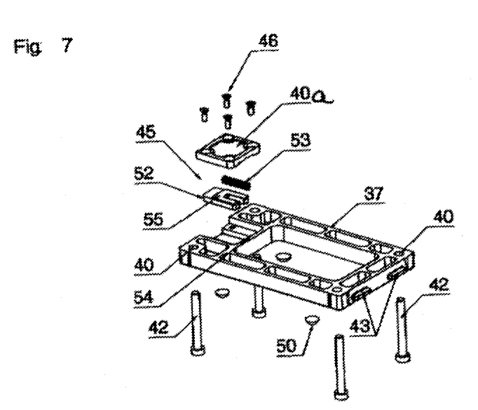

FIG. 7 is an exploded illustration of the holding element of FIG. 6;

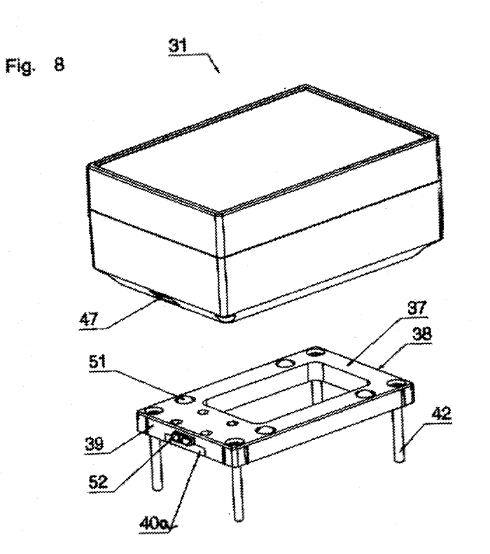

FIG. 8 is a further perspective view of the holding element and the housing that can be arrested thereon; and

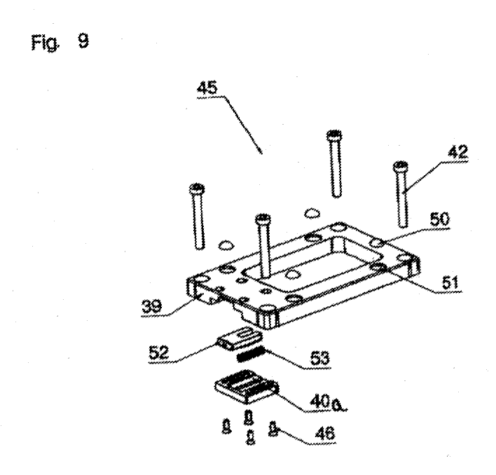

FIG. 9 is a further exploded illustration of the holding element.

The perspective illustrations of FIGS. 1 and 2 show a housing 1 for accommodating electrical and electronic components, the housing being intended for securement to a planar surface, e.g. on a wall or floor surface of a motor vehicle or of a machine. The housing 1 is comprised of a lower portion 2 having a preferably rectangular cross-section and in which are accommodated electrical and electronic components, and of a hood-shaped cover 3 that is screw-connected to the lower portion. For this purpose, four channels 4 are disposed at the corners of the lower portion 2 for non-illustrated screws for the securement of the cover 3. The housing 1 is made of a mechanically resistant material, e.g. of aluminum, a thermoplastic material, or a glass fiber reinforced polyester. On the underside of the lower portion 2, a frame 5 having a rectangular cross-section is integrally formed inwardly of the region of the channels 4, so that the channels are exposed and the screwing-on of the cover 3 is not obstructed.

Fitting into this frame 5 is a holding element 6, which is comprised of a rectangular base plate 7 that corresponds to the inner dimensions of the frame 5 and that, on two oppositely disposed sides, preferably the narrow sides, is respectively bent away at a right angle in the direction toward the base of the lower portion, so that legs 8 and 9 are formed, the lengths of which correspond approximately to the height of the frame 5. In the holding element 6, extending parallel to the longer sides of the rectangular base plate 7, are in each case two slots 10 that extend through the legs 8 and 9, so that four spring brackets or clips 11 are formed that are bent slightly in the direction toward the lower portion 2, so that the ends of the leg portions on the spring clips 11 project beyond the central leg portions that extend between them.

Provided in the planar region of the holding element 6 are bores, four in the illustrated embodiment, through which extend screws 12 via which, during the first stage of assembly of the housing 1, initially the holding element 6 is screwed to the planar securement surface without the housing 1. Via the frame 5 of the lower portion the housing 1 is then placed into the holding element 6. In so doing, a tongue or tab 13, which is bent away at the central leg portion on one side of the holding element 6, first passes into an appropriately fitting slot 14 in the frame 5, and then, by pivoting the opposite side of the housing 1 about the tongue, a latching or arresting mechanism 15 that is provided on the holding element 6 glides over an inclined approach surface 16 on the frame 5 and into the arresting device 17, which in the illustrated embodiment is a hole 17 in the frame 5.

The arresting mechanism is shown in FIG. 2, in which the arrangement of FIG. 1 is illustrated from a different viewpoint or direction of viewing. Here, the arresting mechanism 15 is comprised of a pin 19, which is biased by a compression spring 18 and the end of which is embodied as a hemisphere, and of a hole 20, whereby the rear end of the spring 18 presses against a tab that is bent out of the planar portion of the base plate 7, and the front end of the spring presses the hemispherical pin through the hole 20; after passing the inclined approach surface 16 and achieving a coaxial position relative to the hole 17 in the frame 5 of the lower portion 2 of the housing, the pin can snap through the thickness of the frame 5 and into the hole 17.

The holding element 6 is comprised of a resilient or springing material, preferably steel, whereby the height of the legs 8,9 is approximately equal to the height of the frame 5, so that during the latching or engagement of the housing 1, the free ends of the spring clips 11 spring back and thus ensure a vibration-free arresting between the holding elements 6 and the base of the lower portion 2 of the housing. In so doing, the frame 5 entirely surrounds the holding element 6, so that the securement means are no longer visible from the outside. Since the holding element 6 is positively embraced by the frame 5, a lateral play between these two components is also eliminated.

FIG. 3 shows the housing 1 of FIGS. 1 and 2 with a different embodiment of the holding element. Here, the rectangular base plate 7 is entirely planar, and extending from it, in addition to the legs 8 and 9 on the narrow sides of the base plate 7, on the other two sides are also equally high legs 8a, 9a that extend perpendicular to and upwardly from the base plate 7, so that the legs form a frame into which the frame 5 of the lower portion 2 of the housing fits. Instead of the spring clips 11 formed by the slots 10 in FIGS. 1 and 2, with this embodiment elastically resilient cushions or shock absorbers 21, preferably made of rubber, are secured in the corners of the base plate 7 of the holding element 6, with these shock absorbers extending beyond the legs 8, 8a and 9, 9a of the holding element and being compressed in the arrested or latched-in state, thereby establishing a freedom from play between the lower portion 2 of the housing and the holding element 6. The arresting mechanism 15 has the same configuration as does the embodiment of FIGS. 1 and 2.

FIG. 4a shows the embodiment of FIG. 3 in a 1:1 scale from below with a modified arresting mechanism. FIG. 4 shows a section along the line A-A in FIG. 4a, according to which the frame 5 of the housing portion 6 is hooked into the tongue or tab 13 of the holding element 6, but is not yet arrested at the opposite side into the frame 5.

The arresting mechanism in the encircled portion B of FIG. 4b, which is illustrated in an enlarged scale in FIG. 5, here contains an arresting element 22 that is embodied in the manner of a door lock, and that has a detent 25 thereof pressed against the inner side of the leg 9 by means of a compression spring 23, the rear end of which is supported against the tab 24; an inclined surface of the arresting element 22 extends through a slot in the leg 9, whereby during a pivoting of the housing into the closed position the inclined surface contacts the inclined approach surface 16 of the frame 5 and latches into an opening 17 in the frame 5 that is here embodied as a slot.

The perspective illustrations of FIGS. 6 to 9 show a third embodiment of a holding element 36 and a housing 31 that can be arrested therein. The housing 31 has a configuration that corresponds essentially to the first housing 1, and includes a lower portion 32 and a cover 33 that is screw-connected with the lower portion 32. For the screw connection, for channels 34 are disposed at the corners of the lower portion 32 for non-illustrated screws for the securement of the cover 33. On the underside of the lower portion 32, a rectangular frame 35 is integrally formed within the region of the channels 34 and extends beyond the channels 34 to the outer edge of the lower portion 32.

The holding element 36, which includes a rectangular base plate 37 that corresponds to the inner dimensions of the frame 35, can be positively accommodated in the frame 35. The height of the base plate 37 corresponds approximately to the height of the frame 35, so that the side surfaces of the base plate 37, on two opposite sides, preferably on the narrow sides, form a first leg 38 and a second leg 39 in conformity with the legs 8 and 9 of the first embodiment; the lengths of the legs correspond approximately to the height of the frame 5.

Provided on the four corners of the base plate 7 of the holding element 36 are four through openings 40 through which extend screws 42 via which, during the first stage of assembly of the housing 31, the holding element 36 can be screw-connected to a planar securement surface. For the securement of the housing 1 on the holding element 36, the base plate 37, at the first leg 38, forms two outwardly projecting tongues or tabs 43 that are disposed at an intermediate height; the tongues can be inserted into associated slots 44 of the frame 35. The holding element 46 furthermore includes a latching or arresting mechanism 45, by means of which the holding element 36, on the side of the second leg 39, can catch or be arrested in an arresting device 17 of the frame 35, here also a slot 47. The arresting mechanism 45 has a configuration similar to that of the second embodiment, and includes an arresting element 52, which is embodied in the manner of a door lock and has a detent 55 that, by means of a compression spring 53 supported against a rear wall 54 formed by the base plate 37, is pressed against the inner side of a cover plate 40 that is secured to the base plate 37 via selectively metrical self-tapping screws 46 or screws having lock nuts; an inclined surface of the arresting element 52 extends through a slot formed by the cover plate 40 and the base plate 37 for engagement into the arresting device 47. The arresting process is facilitated by an inclined approach surface 41 that is formed by the frame 35 and that has a configuration that corresponds to the inclined approach surface 16 of the second embodiment. The cover plate 40 covers the arresting mechanism 45 toward the outside.

The base plate 37, cover plate 40 and arresting element 45 are made of polymeric material. Alternatively, however, a metal could also be used, at least for some of the elements. The base plate 37 is open in the central region 48, and is provided with cutouts 49 to reduce material and weight. The holding element 36 additionally includes four rubber cushions or shock absorbers 50, each accommodated in a receiving means 51 of the base plate, whereby in each case two rubber shock absorbers 50 are disposed on each long side of the base plate 37 that is disposed between the legs 38, 39 and faces the housing 1. When the holding element 36 and the housing 31 are in an arrested state, these rubber shock absorbers 50 are compressed, thereby establishing a freedom from play between housing 31 and holding element 36.

In principle, further arresting mechanisms 15, 45 or tongues 13, 43 could be provided. This is particularly advantageous for larger housings.

The present invention is not limited to the illustrated arresting mechanism; rather, other arresting mechanisms could also be utilized in conjunction with the spring means on the holding element.

1-11. (canceled)

12. A housing, comprising:
a lower portion (2, 32);
a cover (3, 33) that is adapted to be secured to said lower portion (2, 32); and
a holding element (6, 36) that is adapted to be mounted on a planar surface, wherein said lower portion (2, 32), with said cover (3, 33) secured thereto, is adapted to be releasably arrested on said holding element (6, 36), under spring tension.

13. A housing according to claim 12, wherein said holding element (6, 36) and said lower portion (2, 32) of said housing are provided with overlapping or interengaging surfaces (5, 8, 9, 35, 38, 39), and wherein a latching or arresting mechanism (15, 45) is disposed between said surfaces.

14. A housing according to claim 13, wherein said holding element (6, 36) is comprised of a square or rectangular base plate (7, 37) that is adapted to be screwed to the planar surface, further wherein said base plate (7, 37) is provided on two opposite sides with legs (8, 9, 38, 39), and that project at right angles from said base plate (7, 37), further wherein a frame (5, 35) is formed on an underside of said lower portion (2, 32) of said housing remote from said cover (3, 33), and wherein said frame (5, 35) is dimensioned such that it positively extends about or embraces said base plate (7, 37) and said legs (8, 9, 38, 39) of said holding element (6, 36).

15. A housing according to claim 14, wherein said legs (8, 9, 38, 39) and said frame (5, 35) have approximately the same height.

16. A housing according to claim 14, wherein one of said legs (8, 38) is provided with a tongue or tab (13, 43), further wherein on a side adjacent to said one leg (8, 38) said frame (5, 35) is provided with at least one opening (14, 44) for introduction of said tongue (13, 43), and wherein on the opposite side of said frame (5, 35), said latching or arresting mechanism (15, 45) is provided between said frame (5, 35) and the other leg (9, 39).

17. A housing according to claim 16, wherein said latching or arresting mechanism (15, 45) is comprised of an arresting element (19, 22, 52) that extends out of said other leg (9, 39) and is movable inwardly against spring force, further wherein said frame (5, 35) is provided with an inclined approach surface (16, 41), further wherein said frame (5, 35) is provided with a receiving means (17, 47), and wherein said arresting element (19, 22, 52), when said frame (5, 35) and said holding element (6, 36) are inserted into one another, snaps or falls into said receiving means 917, 47), or interengages said receiving means, via said inclined approach surface (16, 41) of said frame (5, 35).

18. A housing according to claim 17, wherein said arresting element is a pin (19) having a hemispherical head that extends into a hole (20) provided in said other leg (9).

19. A housing according to claim 17, wherein said arresting element (19) is embodied in the manner of a door lock (22, 52), and wherein said receiving means (17, 47) of said frame (5, 35) is a slot or a projection.

20. A housing according to claim 14, wherein at least two elastically resilient bodies (11, 50) are provided on said holding element (6, 36) and project in the direction toward said lower portion (2, 32), and wherein in an arrested state said elastically resilient bodies (11, 50) bias said holding element (6, 36) and said lower portion (2, 32) against one another.

21. A housing according to claim 20, wherein four elastically resilient brackets or clips (11) are provided on said holding element (6), further wherein said brackets or clips are formed by slots (10) in said base plate (7) and in said legs (8, 9), and wherein said brackets or clips (11) are bent out of the plane of said base plate (7).

22. A housing according to claim 20, wherein elastically resilient, separate cushions or shock absorbers (21, 50) are disposed on said holding element (6, 36), further wherein said cushions or shock absorbers (21, 50) project in the direction toward said lower portion (2, 32), and wherein said cushions or shock absorbers (21, 50) are dimensioned such that they extend beyond said legs (8, 8a, 9, 9a, 38, 39) of said holding element (6, 36) and in an arrested state bias said holding element (6, 36) and said lower portion (2, 32) against one another.
